(19) United States
(12) Patent Application Publication
(10) Pub. No.: US 2026/0265913 A1
(43) Pub. Date: Sep. 10, 2026

(54) GROUP 5 METAL PRECURSOR COMPOUND FOR THIN FILM DEPOSITION, AND METHOD FOR FORMING GROUP 5 METAL-CONTAINING THIN FILM BY USING SAME

(71) Applicant: EGTM Co., Ltd., Suwon-si, Gyeonggi-do (KR)

(72) Inventors: Woong Jin CHOI, Suwon-si (KR); Tae Young LEE, Suwon-si (KR); Shin Beom KIM, Seongnam-si (KR); Sung Jun JI, Suwon-si (KR); Sun Young BAIK, Incheon (KR); Ju Hwan JEONG, Yongin-si (KR); Kyu Ho CHO, Suwon-si (KR)

(21) Appl. No.: 19/161,144

(22) PCT Filed: Mar. 8, 2024
(86) PCT No.: PCT/KR2024/003037

§ 371 Date: Aug. 29, 2025

(30) Foreign Application Priority Data
Mar. 8, 2023 (KR) 10-2023-0030469
Mar. 7, 2024 (KR) 10-2024-0032856

(51) Int. Cl. C23C 16/455; C07F 9/00; C23C 16/40; C23C 16/448

(52) U.S. Cl. CPC C23C 16/45553; C07F 9/00; C23C 16/405; C23C 16/4481

(57) ABSTRACT

According to an embodiment of the present disclosure, a group 5 metal precursor compound is represented by the following Chemical Formula 1.

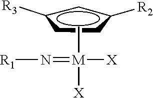

Therefore, the group 5 metal precursor compound according to an embodiment of the present disclosure has excellent thermal stability, exists in a liquid state at room temperature, and is highly volatile so as to be advantageous when applied to a thin film formation process. In addition, if the group 5 metal precursor compound according to an embodiment of the present disclosure is used, a group 5 metal thin film having a low residue amount and uniform physical properties can be obtained, and the thickness of the thin film can be readily controlled.

### TECHNICAL FIELD

The present disclosure relates to a group 5 metal precursor compound and a method of forming a thin film containing a group 5 metal using the same, and more particularly, to a group 5 metal compound capable of forming a thin film containing a group 5 metal with excellent thermal stability, a low growth per cycle (GPC) of the thin film during a deposition process, and a high residue amount, and a method of forming a thin film containing a group 5 metal using the same.

### BACKGROUND ART

With the development of electronic technology, the demand for miniaturization and lightweighting of electronic devices used in various electronic devices is rapidly increasing. Various physical and chemical deposition methods have been proposed to form fine electronic devices, and various studies have been conducted to manufacture various electronic devices, such as metal thin films, metal oxide thin films, or metal nitride thin films by these deposition methods.

In manufacturing semiconductor devices, thin films containing group 5 metal compounds are generally formed using a metal organic chemical vapor deposition (MOCVD) or atomic layer deposition (ALD) process.

Compared to the MOCVD process, the ALD process has advantages of having excellent step coverage due to a self-limiting reaction, and avoiding deterioration of device characteristics caused by thermal diffusion due to a relatively low-temperature process.

In order to deposit thin films containing vanadium (V), niobium (Nb), and tantalum (Ta) among group 5 metal compounds, it is very important to select precursor compounds suitable for the deposition process. There are various types of group 5 metal precursors in the current semiconductor industry. Conventional group 5 metal precursor compounds have the disadvantage of being easily decomposed during a thin film formation process due to low thermal stability to have a high carbon amount in the thin film. In addition, since the growth per cycle (GPC) of the thin film is high, fine thickness adjustment is not easy, and thus it is difficult to form a thin film containing a group 5 metal required for a next-generation semiconductor device.

### DISCLOSURE

### Technical Problem

An object of the present disclosure is to provide a group 5 metal compound that is suitable for thin film growth, has strong thermal stability, and exists in a liquid state at room temperature with a high vapor pressure, thereby solving processing problems caused by using conventional group 5 metal compounds.

Another object of the present disclosure is to provide a group 5 metal compound for thin film deposition capable of providing a high-quality and uniform thin film having a low carbon amount by using the group 5 metal compound.

Yet another object of the present disclosure is to provide a method of forming a thin film containing a group 5 metal capable of fine thickness adjustment using the group 5 metal composition for thin film deposition.

The objects of the present disclosure are not limited to the aforementioned objects, and other objects, which are not mentioned above, will be apparent to those skilled in the art from the following description.

### Technical Solution

One embodiment of the present disclosure provides a group 5 metal compound represented by the following Chemical Formula 1:

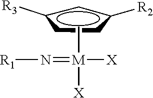

(in Chemical Formula 1, M is any one selected from group 5 metal elements, R₁ is selected from a linear alkyl group having 1 to 4 carbon atoms and a branched alkyl group having 3 to 4 carbon atoms, R₂ and R₃ are each independently selected from a linear alkyl group having 1 to 6 carbon atoms and a branched alkyl group having 3 to 6 carbon atoms, and X is each independently a halogen element.)

Another embodiment of the present disclosure provides a precursor composition for deposition of a thin film containing a group 5 metal element, in which the precursor composition for thin film deposition according to one embodiment of the present disclosure includes the group 5 metal element compound represented by Chemical Formula 1.

Yet another embodiment of the present disclosure provides a method of forming a thin film containing a group 5 metal including depositing a thin film on a substrate using the group 5 metal precursor compound represented by Chemical Formula 1 by a metal organic chemical vapor deposition (MOCVD) process or an atomic layer deposition (ALD) process.

Details of other embodiments will be included in the detailed description of the invention and the accompanying drawings.

### Advantageous Effects

According to an embodiment of the present disclosure, the group 5 metal compound has excellent thermal stability, exists in a liquid state at room temperature, and has a high vapor pressure so as to be advantageous in the thin film by a deposition process. In particular, the group 5 metal precursor compound of the present disclosure has a lower growth per cycle (GPC) of the thin film during deposition than a conventional group 5 metal precursor compound having an amine ligand. Accordingly, when the thin film is formed by an MOCVD deposition process or an ALD deposition process, a high-quality group 5 metal thin film having a low carbon amount can be formed, and fine thickness adjustment is easy, so that a thin film having a desired thickness can be easily formed.

When the ALD deposition process is performed using the group 5 metal precursor compound according to an embodiment of the present disclosure, the quality of the thin film can be further improved due to a constant growth per cycle (GPC) of the thin film in a wider temperature range than that of conventional group 5 metal precursor compounds.

In addition, according to an embodiment of the present disclosure, a group 5 metal compound containing an asymmetric disubstituted cyclopentadiene ligand is more advantageous to liquefy than a group 5 metal compound having a conventional M-Cl (M is any one selected from group 5 metal elements) ligand and has excellent thermal stability, so that a group 5 metal thin film formation process is easy.

In addition, the group 5 metal thin film formed of the group 5 metal compound according to an embodiment of the present disclosure has excellent thermal stability, excellent morphological characteristics, and low diffusivity, low leakage, and low charge trapping properties, and thus can be used for various applications such as dielectrics, prevention films, electrodes, and the like.

The effects according to the present disclosure are not limited by the contents exemplified above, and more various effects are included in the present specification.

### DESCRIPTION OF DRAWINGS

FIG. 1 is a graph showing a growth per cycle of a thin film according to a deposition temperature in an atomic layer deposition process using each of niobium precursor compounds according to Example 1 and Comparative Example 1.

FIG. 2 is a photograph showing thermal stability of each sample according to Example 1 and Comparative Example 1.

FIG. 3 is a graph showing a result of thermogravimetric analysis (TGA) of a niobium precursor compound according to Example 1.

FIG. 4 is a graph showing a result of thermogravimetric analysis (TGA) of a niobium precursor compound according to Comparative Example 1.

FIG. 5 is a graph showing a result of thermogravimetric analysis (TGA) of a niobium precursor compound according to Comparative Example 2.

FIG. 6 is a graph showing a result of thermogravimetric analysis (TGA) of a niobium precursor compound according to Comparative Example 3.

FIG. 7 is a graph showing a result of thermogravimetric analysis (TGA) of a tantalum precursor compound according to Example 4.

FIG. 8 is a graph showing a growth per cycle of a thin film according to a deposition temperature in an atomic layer deposition process using the tantalum precursor compound according to Example 4.

### BEST MODE

Advantages and features of the present disclosure, and methods for achieving the same will be apparent with reference to embodiments to be described below in detail together with the accompanying drawings. However, the present disclosure is not limited to the following embodiments, but may be implemented in various different forms. The embodiments are provided only to complete the disclosure of the present disclosure and to fully inform a person having ordinary skill in the art to which the present disclosure pertains with the category of the invention.

In describing the present disclosure, a detailed description of related known technologies will be omitted if it is determined that they unnecessarily make the gist of the present disclosure unclear. The terms such as “including”, “having”, and “consisting of” used herein are intended to allow other components to be added unless the terms are used with the term “only”. When a component is expressed in a singular form, the singular form may include a plural form unless clearly stated otherwise.

Components are interpreted to include an error range unless otherwise expressly stated.

Throughout the present specification, the term “room temperature” means a temperature of 15° C. to 30° C., or 20° C. to 27° C.

A group 5 metal precursor compound according to an embodiment of the present disclosure may be represented by the following Chemical Formula 1.

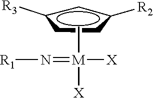

In Chemical Formula 1, M is any one selected from group 5 metal elements, R₁ is selected from a linear alkyl group having 1 to 4 carbon atoms and a branched alkyl group having 3 to 4 carbon atoms, R₂ and R₃ are each independently selected from a linear alkyl group having 1 to 6 carbon atoms and a branched alkyl group having 3 to 6 carbon atoms, and X is each independently a halogen element.

Hereinafter, the compound of Chemical Formula 1 will be described in detail.

In Chemical Formula 1, M may be any one selected from group 5 metal elements. For example, M may be any one selected from the group consisting of niobium (Nb), tantalum (Ta), and vanadium (V), and preferably may be, for example, Nb or Ta. More preferably, M may be Nb, and in this case, the thermal stability of the precursor compound is excellent and the residue amount is low, thereby providing a high-quality thin film.

In Chemical Formula 1, R₁ may be any one selected from a linear alkyl group having 1 to 4 carbon atoms and a branched alkyl group having 3 to 4 carbon atoms. For example, R₁ may be a branched alkyl group having 3 to 4 carbon atoms. In this case, the thermal stability is further excellent, and the vapor pressure is high, so that the precursor compound may exist in a liquid state without solidifying during the thin film formation process.

In Chemical Formula 1, R₂ and R₃ may each independently be any one selected from a linear alkyl group having 1 to 6 carbon atoms and a branched alkyl group having 3 to 6 carbon atoms. As such, when a cyclopentadiene ligand is substituted with substituents R₂ and R₃, the binding affinity between the group 5 metal and the ligand compound may be reduced compared to a group 5 metal compound containing an unsubstituted cyclopentadiene ligand. Accordingly, the unnecessary residue amount in the thin film formed in the deposition process may be reduced.

Preferably, in Chemical Formula 1, R₂ and R₃ may each be a linear alkyl group having 1 to 6 carbon atoms. In this case, the unnecessary residue amount in the thin film during the deposition process is further reduced, thereby providing a high-quality group 5 metal thin film.

In Chemical Formula 1, R₂ and R₃ may be different from each other. As such, when the substituents R₂ and R₃ bound to the cyclopentadiene ligand have different asymmetric structures, the precursor compound may exist in a liquid state at room temperature due to a lower melting point, thereby forming a group 5 metal thin film with high reproducibility and uniform physical properties.

According to an embodiment of the present disclosure, in the case of a group 5 metal compound in which R₂ and R₃ are substituted with different alkyl groups, a group 5 metal compound with an asymmetric structure in which one of R₂ and R₃ is hydrogen has a high vapor pressure characteristic.

In addition, under a condition that the sum of carbon atoms of R₂ and carbon atoms of 0.3 is the same as each other, a group 5 metal compound with an asymmetric structure where R₂ and R₃ are different from each other has a higher vapor pressure than a group 5 metal compound with a symmetric structure where R₂ and R₃ are the same as each other. Accordingly, it is possible to easily form a high-quality group 5 metal thin film through the deposition process.

In Chemical Formula 1, the sum of carbon atoms of R₂ and carbon atoms of 0.3 may be 3 or less. In this case, the group 5 metal compound may exist in a liquid state at room temperature due to excellent thermal stability and a high vapor pressure, thereby easily forming a group 5 metal thin film through the deposition process. In Chemical Formula 1, if the sum of carbon atoms of R₂ and carbon atoms of R₃ is greater than 3, the group 5 metal compound may exist in a liquid state at room temperature, but may exhibit high viscosity. Accordingly, in terms of ease of the process and formation of a high-quality group 5 metal thin film, the sum of carbon atoms of R₂ and carbon atoms of R₃ in Chemical Formula 1 may be 3 or less.

In Chemical Formula 1, X may each independently be a halogen element. Specifically, for example, X may each independently be any one selected from the group consisting of fluorine (F), chlorine (Cl), bromine (Br), and iodine (I), and preferably, for example, X may each be chlorine (Cl).

A conventional precursor compound such as MCl₅ (M is any one selected from group 5 metal elements) consists of only M-X (X is a halogen element, and may be any one selected from the group consisting of fluorine (F), chlorine (Cl), bromine (Br), and iodine (I)) having higher binding energy than M-N bonds and N—C bonds, and thus has excellent thermal stability, but has a high residue amount and exists in a solid at room temperature, and thus has a problem in that the deposition process is not easy and the quality of the thin film is ununiform.

The group 5 metal precursor compound according to an embodiment of the present disclosure includes M-X and M═N bonds, and cyclopentadiene substituted with two substituents is bonded to an M-centered metal, so that the group 5 metal precursor compound has better thermal stability than conventional group 5 metal precursors and exists in a liquid state at room temperature to facilitate a deposition process, and may form a group 5 metal thin film having regular and uniform physical properties.

More specifically, the group 5 metal compound may be selected from compounds represented by the following Chemical Formulas 2, 3, and 4.

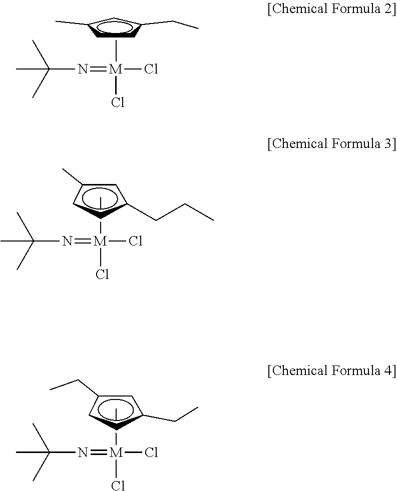

In Chemical Formulas 2, 3, and 4, M may each independently be any one selected from the group consisting of niobium (Nb), tantalum (Ta), and vanadium (V) as group 5 metal elements.

More preferably, the group 5 metal compound may be a compound represented by the following Chemical Formula 2. The group 5 metal compound may provide a group 5 metal thin film having the best thermal stability and excellent physical properties due to a smaller residue amount, and has the advantage of easy thickness control due to a low thin film growth per cycle (GPC).

The group 5 metal compound represented by Chemical Formula 1 according to an embodiment of the present disclosure exists in a liquid state at room temperature, making it easy to store and handle, and may be advantageously applied to form a thin film using the deposition process.

Accordingly, the group 5 metal compound represented by Chemical Formula 1 according to an embodiment of the present disclosure may be used as a precursor for manufacturing a group 5 metal thin film through an MOCVD deposition process or an ALD deposition process.

In addition, the group 5 metal compound represented by Chemical Formula 1 exhibits a constant thin film growth per cycle (GPC) in a wide temperature range in the deposition process, and has the advantage of being easy to adjust the thickness and being able to finely adjust the thickness because the thin film GPC is low.

Accordingly, the group 5 metal compound represented by Chemical Formula 1 may be used as a precursor composition for deposition of a thin film containing a group 5 metal.

Hereinafter, a method of forming a thin film containing a group 5 metal according to an embodiment of the present disclosure will be described in detail. In the method of forming the thin film containing the group 5 metal, the group 5 metal compound described above is used, and the duplicated description related to the group 5 metal compound will be omitted.

In the method of forming the thin film containing the group 5 metal according to an embodiment of the present disclosure, a thin film is deposited on a substrate through a deposition process using the group 5 metal precursor compound represented by Chemical Formula 1.

The deposition process may be performed by an atomic layer deposition (ALD) process or a chemical vapor deposition (CVD) process, for example, a metal organic chemical vapor deposition (MOCVD) process. The deposition process may be performed at 50° C. to 700° C.

First, the group 5 metal precursor compound represented by Chemical Formula 1 is transferred onto the substrate. For example, the group 5 metal precursor compound may be supplied onto the substrate by a bubbling method, a vapor phase mass flow controller method, a direct gas injection (DGI) method, a direct liquid injection (DLI) method, a liquid transfer method to be dissolved and transferred in an organic solvent, and the like, but is not limited thereto.

If necessary, the group 5 metal precursor compound may be supplied together with carrier gas or dilution gas. The carrier gas is not reactive with the group 5 metal precursor compound and is lighter than the group 5 metal precursor compound to easily transfer the vaporized group 5 metal precursor compound to a reaction chamber. The dilution gas is not reactive with the group 5 metal precursor compound so as not to cause side reactions, and the flow rate thereof may be controlled to easily control the reaction such as a growth per cycle of the thin film, etc. For example, each of the carrier gas and the dilution gas may be at least one selected from the group consisting of argon (Ar), nitrogen (N₂), helium (He), and hydrogen (H₂).

For example, the group 5 metal precursor compound may be mixed with carrier gas or dilution gas containing at least one selected from the group consisting of argon (Ar), nitrogen (N₂), helium (He), and hydrogen (H₂) to be transferred onto the substrate by a bubbling method or a direct gas injection method.

In the deposition process for forming the group 5 metal thin film, various thin films containing group 5 metals such as a group 5 metal oxide thin film, a group 5 metal carbon oxide thin film, and a group 5 metal nitride thin film may also be formed by supplying reaction gas as necessary. The reaction gas may be supplied in the step of depositing the thin film.

For example, the reaction gas may include at least one selected from the group consisting of water vapor (H₂O), oxygen (O₂), ozone (O₃), hydrogen peroxide (H₂O₂), ammonia (NH₃), hydrazine (N₂H₄), nitrous oxide (N₂O), and nitrogen (N₂).

For example, when the group 5 metal oxide thin film or the group 5 metal carbon oxide thin film is to be manufactured, reaction gas containing oxygen may be supplied. For example, the reaction gas containing oxygen may include at least one selected from the group consisting of water vapor (H₂O), oxygen (O₂), oxygen plasma, ozone (O₃), and hydrogen peroxide (H₂O₂). Such a reaction gas may react with the group 5 metal compound in the thin film deposition process to form the group 5 metal oxide thin film or the group 5 metal carbon oxide thin film.

As another example, when the group 5 metal nitride thin film is to be manufactured, the reaction gas containing nitrogen may be supplied. For example, the reaction gas containing nitrogen may include at least one selected from the group consisting of ammonia (NH₃), hydrazine (N₂H₄), nitrous oxide (N₂O), and nitrogen (N₂). Such a reaction gas may react with the group 5 metal compound in the thin film deposition process to form the group 5 metal nitride thin film.

After the group 5 metal precursor compound of Chemical Formula 1 is supplied onto the substrate, when thermal energy, plasma, electrical bias, or the like is applied, decomposition and condensation reactions of the group 5 metal precursor compound proceed, and thus a thin film containing a group 5 metal is formed.

When a thin film having a desired thickness is formed, the method may include purging inert gas such as argon (Ar), nitrogen (N₂), helium (He), and/or hydrogen (H₂) from a reaction chamber to remove the remaining group 5 metal precursor compound which is not reacted.

In the group 5 metal thin film manufactured by the method of forming the thin film according to an embodiment of the present disclosure, the residue amount is effectively reduced, thereby providing a high-quality thin film. In addition, according to the method of forming the thin film according to an embodiment of the present disclosure, it is possible to provide a group 5 metal thin film having more uniform physical properties by exhibiting a constant thin film growth per cycle within a wide thin film growth temperature range, and to finely control a thickness because the thin film growth per cycle is low.

### Modes

Hereinafter, a group 5 metal precursor compound according to the present disclosure will be described in more detail through the following Examples. However, these Examples are only presented to aid the understanding of the present disclosure, and the present disclosure is not limited to the following Examples.

### Example 1

In a flame-dried 1000 mL Schlenk flask, 68.2 g (0.252 mol, 1 eq) of niobium tetrachloride NbCl₅ and 500 mL of dichloromethane were added and then stirred at room temperature. 49.9 g (0.278 mol, 1.1 eq) of (EtMeCp)Si(Me)₃ was added dropwise to the flask at −20×C or lower, and then the reaction solution was stirred at room temperature for 12 hours. Thereafter, the solvent was removed under reduced pressure to obtain a dark red solid compound represented by (EtMeCp)Nb(Cl)₄. Thereafter, 55.4 g (0.757 mol, 3 eq) of tert-butylamine was added, and then the reaction solution was stirred at room temperature for 12 hours. Thereafter, the solvent was removed under reduced pressure, and 300 mL of hexane was added thereto, and then stirred for 1 hour. Thereafter, the reaction solution was filtered and then distilled under reduced pressure to separate materials dissolved in the hexane to obtain 28.3 g of a red liquid compound.

The synthesis of a niobium precursor compound (tBuN)Nb(EtMeCp)(Cl)₂ represented by the following Chemical Formula 2a was confirmed by nuclear magnetic resonance analysis (¹H NMR).

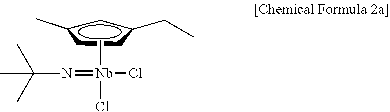

### Example 2

In a flame-dried 1000 mL Schlenk flask, 68.2 g (0.252 mol, 1 eq) of niobium tetrachloride NbCl₅ and 500 mL of dichloromethane were added and then stirred at room temperature. 53.8 g (0.278 mol, 1.1 eq) of (nPrMeCp)Si(Me)₃ was added dropwise to the flask at −20° C. or lower, and then the reaction solution was stirred at room temperature for 12 hours. Thereafter, the solvent was removed under reduced pressure to obtain a dark red solid compound represented by (nPrCp)Nb(Cl)₄. Thereafter, 55.4 g (0.757 mol, 3 eq) of tert-butylamine was added, and then the reaction solution was stirred at room temperature for 12 hours. Thereafter, the solvent was removed under reduced pressure, and 300 mL of hexane was added thereto, and then stirred for 1 hour. Thereafter, the reaction solution was filtered and then distilled under reduced pressure to separate materials dissolved in the hexane to obtain 24.3 g of a red liquid compound.

The synthesis of a niobium precursor compound (tBuN)Nb(nPrMeCp)(Cl)₂ represented by the following Chemical Formula 3a was confirmed by nuclear magnetic resonance analysis (1H NMR).

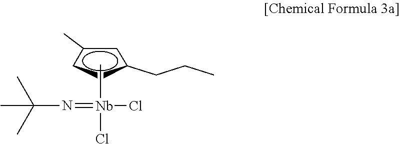

### Example 3

In a flame-dried 1000 mL Schlenk flask, 68.2 g (0.252 mol, 1 eq) of niobium tetrachloride NbCl₅ and 500 mL of dichloromethane were added and then stirred at room temperature. 53.8 g (0.278 mol, 1.1 eq) of (Et₂Cp)Si(Me)₃ was added dropwise to the flask at −20° C. or lower, and then the reaction solution was stirred at room temperature for 12 hours. Thereafter, the solvent was removed under reduced pressure to obtain a dark red solid compound represented by (Et₂Cp)Nb(Cl)₄. Thereafter, 55.4 g (0.757 mol, 3 eq) of tert-butylamine was added, and then the reaction solution was stirred at room temperature for 12 hours. Thereafter, the solvent was removed under reduced pressure, and 300 mL of hexane was added thereto, and then stirred for 1 hour. Thereafter, the reaction solution was filtered and then distilled under reduced pressure to separate materials dissolved in the hexane to obtain 21.5 g of a red liquid compound.

The synthesis of a niobium precursor compound (tBuN)Nb(Et₂Cp)(Cl)₂ represented by the following Chemical Formula 4 was confirmed by nuclear magnetic resonance analysis (1H NMR).

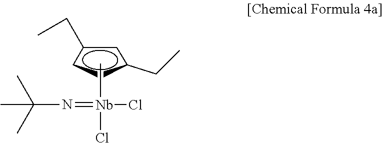

### Example 4

In a flame-dried 1000 mL Schlenk flask, 90.3 g (0.252 mol, 1 eq) of tantalum tetrachloride TaCl₅ and 500 mL of dichloromethane were added and then stirred at room temperature. 49.9 g (0.278 mol, 1.1 eq) of (EtMeCp)Si(Me)₃ was added dropwise to the flask at −20° C. or lower, and then the reaction solution was stirred at room temperature for 12 hours. Thereafter, the solvent was removed under reduced pressure to obtain a dark red solid compound represented by (EtMeCp)Nb(Cl)₄. Thereafter, 55.4 g (0.757 mol, 3 eq) of tert-butylamine was added, and then the reaction solution was stirred at room temperature for 12 hours. Thereafter, the solvent was removed under reduced pressure, and 300 mL of hexane was added thereto, and then stirred for 1 hour. Thereafter, the reaction solution was filtered and then distilled under reduced pressure to separate materials dissolved in the hexane to obtain 22.3 g of a light yellow liquid compound.

The synthesis of a tantalum precursor compound (tBuN)Ta(EtMeCp)(Cl)₂ represented by the following Chemical Formula 2b was confirmed by nuclear magnetic resonance analysis (1H NMR).

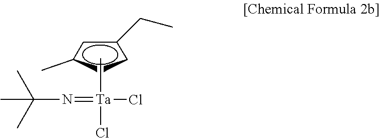

### Comparative Example 1

In a flame-dried 2000 mL Schlenk flask, 65.0 g (0.241 mol, 1 eq) of niobium tetrachloride NbCl₅ and 78.7 g (0.577 mol, 2.4 eq) of zinc chloride (ZnCl₂) were added with 500 mL of toluene. Thereafter, 52.8 g (0.722 mol, 3 eq) of tert-butylamine was added dropwise at −20° C. or lower, and then stirred at room temperature for 4 hours. Thereafter, 45.5 g (0.505 mol, 2.1 eq) of 1,2-dimethoxethane was added dropwise at −20° C. or lower, and then the reaction solution was stirred at room temperature for 12 hours.

Thereafter, 466 ml (0.746 mol, 3.1 eq) of a 1.6 M lithium dimethylamine solution dissolved in tetrahydrofuran was added dropwise to the flask at −20° C. or lower, and then the reaction solution was stirred at room temperature for 12 hours. Then, 17.5 g (0.265 mol, 1.1 eq) of cyclopentadiene was added dropwise at −20° C. or lower, and then the reaction solution was stirred at room temperature for 12 hours. Then, the reaction solution was filtered and then distilled under reduced pressure to separate materials dissolved in the solvent to obtain 23.4 g of a yellow liquid compound.

The synthesis of a niobium precursor compound (tBuN)Nb(Cp)(DMA)₂ represented by the following Chemical Formula 5 was confirmed by nuclear magnetic resonance analysis (¹H NMR).

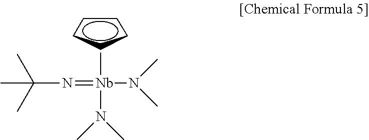

### Comparative Example 2

In a flame-dried 1000 mL Schlenk flask, 68.2 g (0.252 mol, 1 eq) of niobium tetrachloride NbCl₅ and 500 mL of dichloromethane were added and then stirred at room temperature. 49.9 g (0.278 mol, 1.1 eq) of (EtMeCp)Si(Me)₃ was added dropwise to the flask at −20° C. or lower, and then the reaction solution was stirred at room temperature for 12 hours. Thereafter, the solvent was removed under reduced pressure to obtain a dark red solid compound represented by (EtMeCp)Nb(Cl)₄. Thereafter, 66.0 g (0.757 mol, 3 eq) of tert-amylamine was added, and then the reaction solution was stirred at room temperature for 12 hours. Thereafter, the solvent was removed under reduced pressure, and 300 mL of hexane was added thereto, and then stirred for 1 hour. Thereafter, the reaction solution was filtered and then distilled under reduced pressure to separate materials dissolved in the hexane to obtain 30.4 g of a red liquid compound.

The synthesis of a niobium precursor compound (t-AmylN)Nb(EtMeCp)(Cl)₋₂ represented by the following Chemical Formula 6 was confirmed by nuclear magnetic resonance analysis (¹H NMR).

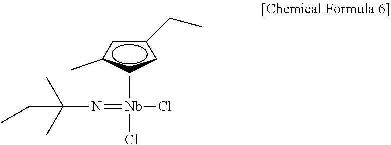

### Comparative Example 3

In a flame-dried 1000 mL Schlenk flask, 68.2 g (0.252 mol, 1 eq) of niobium tetrachloride NbCl₅ and 500 mL of dichloromethane were added and then stirred at room temperature. 49.9 g (0.278 mol, 1.1 eq) of (PrCp)Si(Me)₃ was added dropwise to the flask at −20° C. or lower, and then the reaction solution was stirred at room temperature for 12 hours. Thereafter, the solvent was removed under reduced pressure to obtain a dark red solid compound represented by (PrCp)Nb(Cl)₄. Thereafter, 55.4 g (0.757 mol, 3 eq) of tert-butylamine was added, and then the reaction solution was stirred at room temperature for 12 hours. Thereafter, the solvent was removed under reduced pressure, and 300 mL of hexane was added thereto, and then stirred for 1 hour. Thereafter, the reaction solution was filtered and then distilled under reduced pressure to separate materials dissolved in the hexane to obtain 27.1 g of a red liquid compound.

The synthesis of a niobium precursor compound (tBuN)Nb(PrCp)(Cl)₂ represented by the following Chemical Formula 7 was confirmed by nuclear magnetic resonance analysis (H NMR).

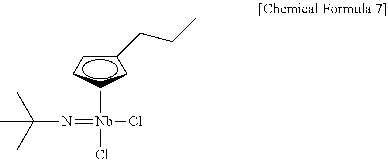

### [Experimental Example]

### 1. Evaluation of Thermal Stability

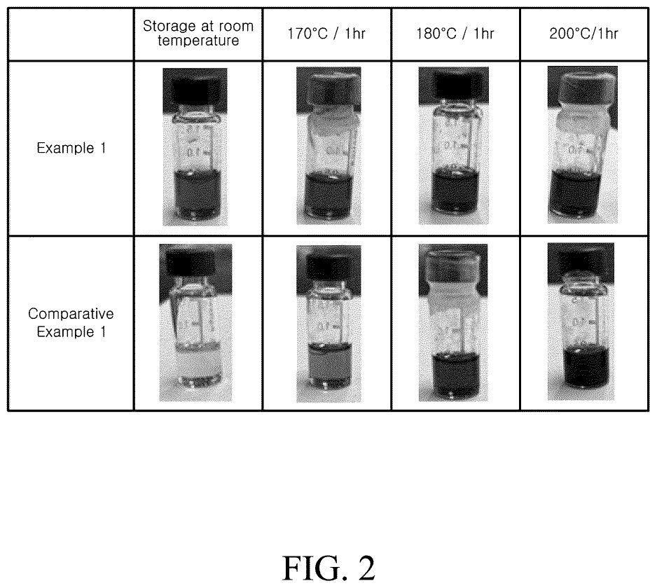

In order to determine the thermal stability of the compounds according to Example 1 and Comparative Example 1, 0.7 ml of the compound of Example 1 was added to each of three high-pressure reactors, and 0.7 ml of the compound of Comparative Example 1 was added to each of three high-pressure reactors to prepare samples. The samples of each of Example 1 and Comparative Example 1 were heated in a furnace heated to 170° C., 180° C. and 200° C. for 1 hour, and then cooled at room temperature. A photograph of each sample cooled at room temperature was shown in FIG. 2.

Referring to FIG. 2, in the case of the group 5 metal precursor compound of Example 1, it can be confirmed that there was no color change at 170° C., and there were slight color changes at 180° C. and 200° C. Unlike this, in the case of the group 5 metal precursor compound of Comparative Example 1, it can be confirmed that the color became darker at 170° C. than at room temperature, the color became even darker at 180° C., and the color changed to a very dark color close to black at 200° C.

The group 5 metal precursor of Example 1 includes M-Cl bonds, which have a greater binding energy than M-N bonds included in the group 5 metal precursor of Comparative Example 1. Accordingly, it can be determined that the group 5 metal precursor compound of Example 1 exhibits high thermal stability including M-Cl bonds having larger binding energy than the group 5 metal precursor compound of Comparative Example 1.

### 2. Thermogravimetric Analysis

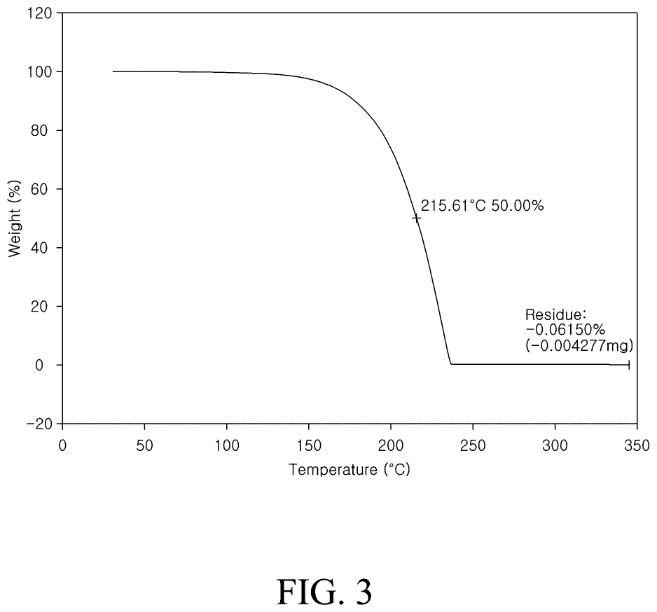

To determine the thermal characteristics of the compounds according to Examples 1 to 4, and Comparative Examples 1 to 3, thermogravimetric analysis (TGA) was performed. First, the TGA equipment was stored in a nitrogen glove box where the moisture and oxygen contents were maintained at less than 1 ppm. 10 mg of a sample was placed in a crucible, and then measured while heating from 35° C. to 350° C. at a rate of 10° C./min. The mass loss of the sample was monitored as a function of the crucible temperature. The results were shown in Table 1 and FIGS. 3 to 7.

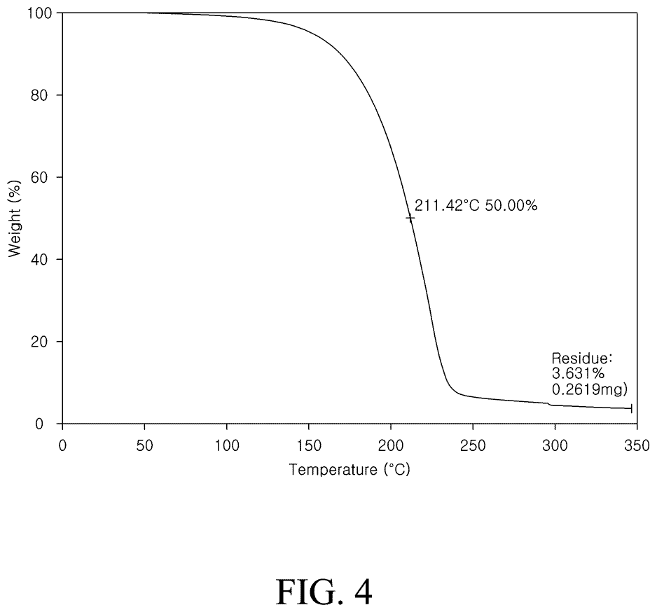

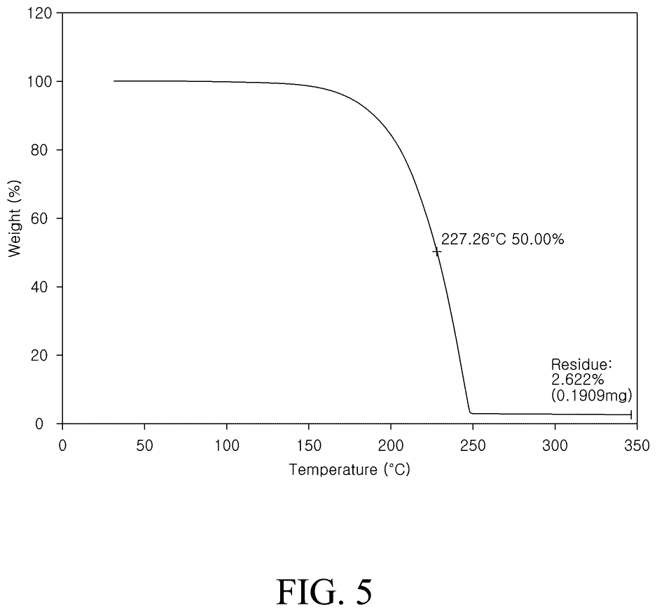

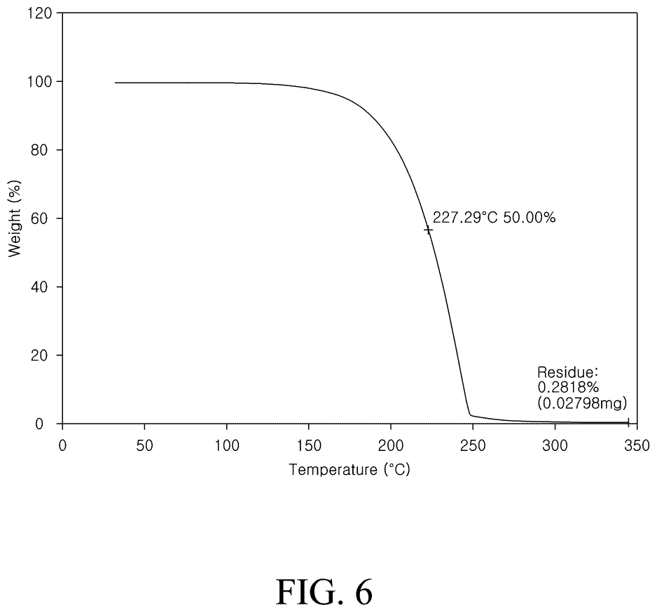

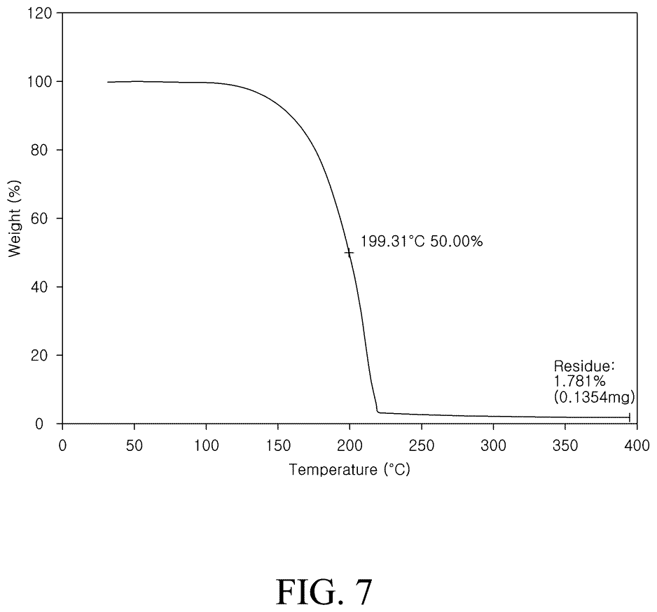

FIG. 3 is a graph showing a result of thermogravimetric analysis (TGA) of a group 5 metal precursor compound according to Example 1, FIG. 4 is a graph showing a result of thermogravimetric analysis (TGA) of a group 5 metal precursor compound according to Comparative Example 1, FIG. 5 is a graph showing a result of thermogravimetric analysis (TGA) of a group 5 metal precursor compound according to Comparative Example 2, FIG. 6 is a graph showing a result of thermogravimetric analysis (TGA) of a group 5 metal precursor compound according to Comparative Example 3, and FIG. 7 is a graph showing a result of thermogravimetric analysis (TGA) of a group 5 metal precursor compound according to Example 4.

TABLE 1

| | Ex. 1 | Ex. 2 | Ex. 3 | Ex. 4 | Com. Ex. 1 | Com. Ex. 2 | Com. Ex. 3 |
|---|---|---|---|---|---|---|---|
| T_{1/2} (° C.) | 215.6 | 245 | 251 | 199.3 | 211.0 | 227.3 | 227.3 |
| Td (° C.) | 327 | 310 | 359 | 316 | 299 | 309 | 308 |

Referring to Table 1 and FIGS. 3 to 7 together, it can be seen that the group 5 metal compound precursors according to Examples 1 to 4 have higher pyrolysis temperatures than the group 5 metal compound precursors according to Comparative Examples 1 to 3, respectively. From this, it can be seen that the compounds of Examples 1 to 4 have excellent thermal stability compared to Comparative Examples. In particular, it can be confirmed that the compounds of Examples 1 to 3 containing a niobium metal element have better thermal stability than Example 4 containing a tantalum metal element. In addition, referring to FIGS. 3 to 7, it can be seen that the group 5 metal precursor compounds prepared according to Examples 1 and 4, and Comparative Examples 1 to 3 have less than about 4 wt % of a non-volatile residue amount at a temperature of 350° C. or higher, respectively, and the residue amount of the compounds according to Examples 1 and 4 is less than the residue amount of the compounds according to Comparative Examples 1 to 3. Further, referring to FIGS. 3 and 7, it can be confirmed that when a type of ligand is the same, the compound of Example 1 containing a niobium metal has better thermal stability and a smaller residue amount than the compound of Example 4 containing a tantalum metal. In addition, although a vapor pressure difference between the compound of Example 1 and the compound of Comparative Example 1 is not large, it can be confirmed that the pyrolysis temperature of the compound of Example 1 is about 30° C. higher than that of the compound of Comparative Example 1.

In addition, when the results of Example 1 and Comparative Example 2 are compared, it can be confirmed that when R₁ in Chemical Formula 1 is a tert-butylamine group having 4 carbon atoms, the vapor pressure is higher and the pyrolysis temperature is also higher than those of the compound to which a tert-amylamine group having 5 carbon atoms is bonded.

In addition, each of the compounds of Example 1 and Comparative Example 3 has the same total of four carbon atoms of the substituents substituted in cyclopentadiene, but when a methyl group and an ethyl group are asymmetrically bonded to the cyclopentadiene as in Example 1, it can be confirmed that the vapor pressure is higher and the pyrolysis temperature is also higher than those of the compound in which only a propyl group is bonded as in Comparative Example 3.

Meanwhile, the compounds of Examples 1 and 3 have the same total of four carbon atoms, but Example 1 has a structure in which a methyl group and an ethyl group are asymmetrically bonded to cyclopentadiene, and Example 3 has a structure in which two ethyl groups are bonded to cyclopentadiene. Comparing the results of Examples 1 and 3, it can be confirmed that the pyrolysis temperature of Example 3 is higher than that of Example 1, but in the case of Example 1, the pyrolysis temperature and the vapor pressure are satisfied at the same time, which is more advantageous in the process.

In addition, although the compounds of Examples 1 and 3 are equivalent in that two substituents are asymmetrically bonded to cyclopentadiene, it can be confirmed that the compound of Example 1 having a total of three carbon atoms of the substituent bonded to cyclopentadiene satisfies the pyrolysis temperature and the vapor pressure at the same time, which is more advantageous in the process. Further, it was confirmed that the viscosity of the compound of Example 1 having a total of three carbon atoms of the substituent bonded to cyclopentadiene was 32.15 cP, but the viscosity of the compound of Example 2 having a total of four carbon atoms of the substituent bonded to cyclopentadiene was high as 84.33 cP. From this, it can be seen that the compound of Example 1 having a total of three carbon atoms of the substituent bonded to cyclopentadiene and an asymmetric structure of two substituents bonded to cyclopentadiene has a low viscosity, which is more advantageous in the deposition process.

### 3. Thin Film Deposition Property

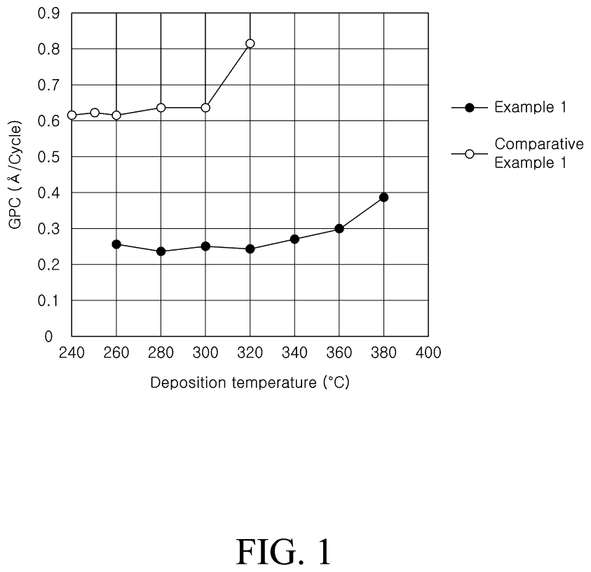

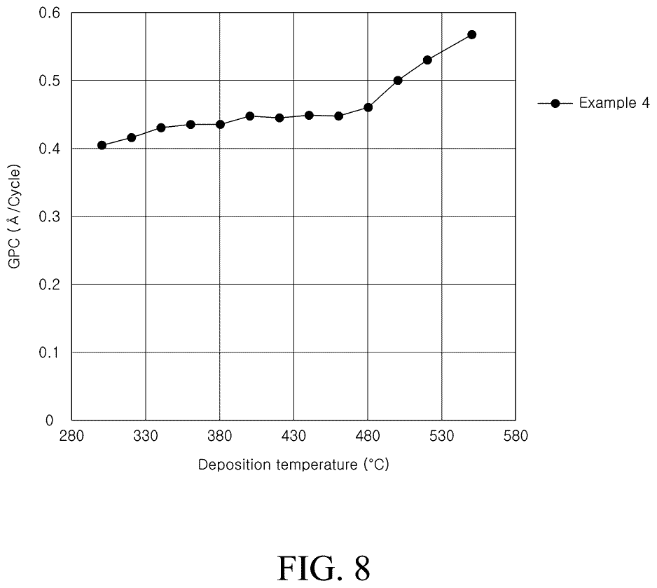

The growth per cycle of the thin film in the atomic layer deposition process using the group 5 metal precursor compounds according to Examples 1 and 4 and Comparative Example 1 was analyzed, respectively. The results thereof were shown in FIGS. 1 and 8.

First, FIG. 1 is a graph showing a growth per cycle (GPC) of the thin film according to a deposition temperature in an atomic layer deposition process using each of group 5 metal precursor compounds according to Example 1 and Comparative Example 1.

For the deposition conditions, each of the niobium precursor compounds according to Example 1 and Comparative Example 1 was filled in a canister, and then heated to 110° C., and ozone (O₃) was used as an oxidizing agent. A silicon wafer was used as a reaction substrate, and heated from 250° C. to 400° C. to perform deposition. After the pulse of the precursor was introduced for 10 seconds, argon (Ar) was purged for 10 seconds. Then, the pulse of ozone (O₃) was introduced into the reaction chamber for 15 seconds, and then argon (Ar) was purged for 10 seconds. 80 to 100 cycles were performed in the same manner. In such a manner, a group 5 metal oxide thin film having the same thickness was formed for each precursor.

Referring to FIG. 1, it can be seen that in the case of using the group 5 metal precursor compound according to Example 1 in the atomic layer deposition process, the growth per cycle of the thin film is lower than that in the case of using the group 5 metal precursor compound of Comparative Example 1, and the growth per cycle of the thin film is kept constant within a wide temperature range.

In the atomic layer deposition process, the fact that the growth per cycle of the thin film is kept constant means that the thin film is stably formed without occurrence of side reactions, such as an incomplete reaction, deposition in a precursor state without a chemical reaction, or decomposition by heat. That is, it can be seen from FIG. 1 that in the case of using the group 5 metal precursor compound according to Example 1, a stable thin film deposition process is enabled compared to the case of using the group 5 metal precursor compound of Comparative Example 1.

In particular, in the case of using the group 5 metal precursor compound according to Example 1, it can be seen that a uniform group 5 metal thin film having excellent physical properties may be obtained by exhibiting an almost constant thin film growth per cycle within a deposition temperature range. It can be determined as a result of the group 5 metal precursor compound of Example 1 represented by Chemical Formula 2a including M-Cl bonds to form a more stable structure than the compound of Comparative Example 1 including M-N bonds.

FIG. 8 is a graph showing a growth per cycle (GPC) of the thin film according to a deposition temperature in an atomic layer deposition process using the group 5 metal precursor compound according to Example 4.

For the deposition conditions, the compound represented by Chemical Formula 2b, which was the group 5 metal precursor compound in Example 4, was filled in a canister, and then heated to 110° C., and ozone (O₃) was used as an oxidizing agent. A silicon wafer was used as a reaction substrate, and heated from 300° C. to 550° C. to perform deposition. The pulse of the precursor was introduced for 3 seconds, and then argon (Ar) was purged for 15 seconds. Then, the pulse of ozone (O₃) was introduced into the reaction chamber for 3 seconds, and then argon (Ar) was purged for 15 seconds. 100 cycles were performed in the same manner.

Referring to FIG. 8, it can be seen that the growth per cycle of the thin film is kept constant within a very wide temperature range when the atomic layer deposition process is performed using the precursor compound represented by Chemical Formula 2b according to Example 4. In particular, as compared with the compound of Comparative Example 1 shown in FIG. 1 above, it can be confirmed that the growth per cycle of the thin film is relatively low and constant even at 500° C. or higher.

Accordingly, in the case of using the precursor compound represented by Chemical Formula 2b according to Example 4, it can be seen that a uniform group 5 metal thin film having excellent physical properties may be obtained by exhibiting an almost constant thin film growth per cycle within a deposition temperature range. This can be determined as a result of the group 5 metal precursor compound of Example 4 represented by Chemical Formula 2b including M-Cl bonds to form a stable structure.

A group 5 metal precursor compound, a precursor composition for deposition of a thin film containing a group 5 metal, and a method of forming a thin film containing a group 5 metal according to various embodiments of the present disclosure may be described as follows.

A precursor compound containing a group 5 metal according to an embodiment of the present disclosure is represented by the following Chemical Formula 1.

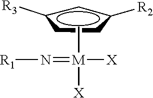

In Chemical Formula 1, M is any one selected from the group consisting of niobium (Nb), tantalum (Ta), and vanadium (V) of group 5 metal elements, R₁ is selected from a linear alkyl group having 1 to 4 carbon atoms and a branched alkyl group having 3 to 4 carbon atoms, R₂ and R₃ are each independently selected from a linear alkyl group having 1 to 6 carbon atoms and a branched alkyl group having 3 to 6 carbon atoms, and X is each independently a halogen element.

According to another feature of the present disclosure, in Chemical Formula 1, R₁ may be a branched alkyl group having 3 to 4 carbon atoms, and R₂ and R₃ may each be a linear alkyl group having 1 to 6 carbon atoms.

According to yet another feature of the present disclosure, R₂ and R₃ may be different from each other.

According to yet another feature of the present disclosure, the sum of carbon atoms of R₂ and carbon atoms of R₃ may be 3 or less.

According to yet another feature of the present disclosure, the group 5 metal precursor compound may be selected from compounds represented by the following Chemical Formulas 2, 3, and 4.

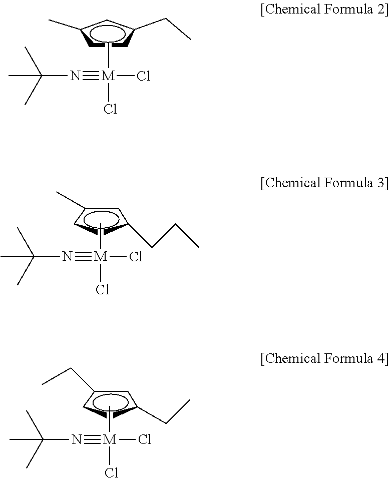

In Chemical Formulas 2, 3, and 4, M may each independently be any one selected from the group consisting of niobium (Nb), tantalum (Ta), and vanadium (V) as group 5 metal elements.

According to yet another feature of the present disclosure, the group 5 metal precursor compound may be in a liquid state at room temperature.

A precursor composition for deposition of a thin film containing a group 5 metal according to an embodiment of the present disclosure includes a group 5 metal precursor compound represented by Chemical Formula 1.

A method of forming a thin film containing a group 5 metal according to an embodiment of the present disclosure provides a method of forming a thin film containing a group 5 metal by depositing a thin film on a substrate using the group 5 metal precursor compound represented by Chemical Formula 1 by a metal organic chemical vapor deposition (MOCVD) process or an atomic layer deposition (ALD) process.

According to another feature of the present disclosure, the deposition process may be performed in the temperature range of 50 to 700° C.

According to yet another feature of the present disclosure, the deposition process may include transferring the group 5 metal precursor compound to the substrate through one method selected from the group consisting of a bubbling method, a vapor phase mass flow controller (MFC) method, a direct gas injection (DGI) method, a direct liquid injection (DLI) method, and an organic solution supply method of dissolving and transferring the group 5 metal precursor compound in an organic solvent.

According to yet another feature of the present disclosure, the group 5 metal precursor compound may be transferred onto the substrate together with carrier gas by the bubbling method or the direct liquid injection method, and the carrier gas may include at least one selected from the group consisting of argon (Ar), nitrogen (N₂), helium (He), and hydrogen (H₂).

According to yet another feature of the present disclosure, the deposition process may include supplying at least one reaction gas selected from the group consisting of water vapor (H₂O), oxygen (O₂), ozone (O₃), and hydrogen peroxide (H₂O₂), when forming the thin film containing the group 5 metal.

According to yet another feature of the present disclosure, the deposition process may include supplying at least one reaction gas selected from the group consisting of ammonia (NH₃), hydrazine (N₂H₄), nitrous oxide (N₂O), and nitrogen (N₂), when forming the thin film containing the group 5 metal.

Hereinabove, although the present disclosure has been described above in detail with reference to embodiments, the present disclosure is not necessarily limited to these embodiments, and may be modified in various forms without departing from the technical spirit of the present disclosure. Accordingly, the embodiments disclosed in the present disclosure are not intended to limit the technical spirit of the present disclosure, but to describe the present disclosure and the technical spirit of the present disclosure is not limited by these embodiments. Therefore, it should be understood that the above-described embodiments are illustrative in all aspects and do not limit the present disclosure. The protective scope of the present disclosure should be construed on the basis of the appended claims, and all the technical ideas in the equivalent scope thereof should be construed as falling within the scope of the present disclosure.

1. A group 5 metal precursor compound represented by the following Chemical Formula 1: 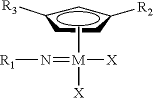
in Chemical Formula 1,
M is any one selected from the group consisting of niobium (Nb), tantalum (Ta), and vanadium (V) as group 5 metal elements,
R₁ is selected from a linear alkyl group having 1 to 4 carbon atoms and a branched alkyl group having 3 to 4 carbon atoms,
R₂ and R₃ are each independently selected from a linear alkyl group having 1 to 6 carbon atoms and a branched alkyl group having 3 to 6 carbon atoms, and
X is each independently a halogen element.

2. The group 5 metal precursor compound of claim 1, wherein in Chemical Formula 1, R₁ is a branched alkyl group having 3 to 4 carbon atoms and R₂ and R₃ are each a linear alkyl group having 1 to 6 carbon atoms.

3. The group 5 metal precursor compound of claim 1, wherein R₂ and R₃ are different from each other.

4. The group 5 metal precursor compound of claim 1, wherein a sum of carbon atoms of R₂ and carbon atoms of R₃ is 3 or less.

5. The group 5 metal precursor compound of claim 1, wherein the group 5 metal precursor compound is selected from compounds represented by the following Chemical Formulas 2, 3, and 4: 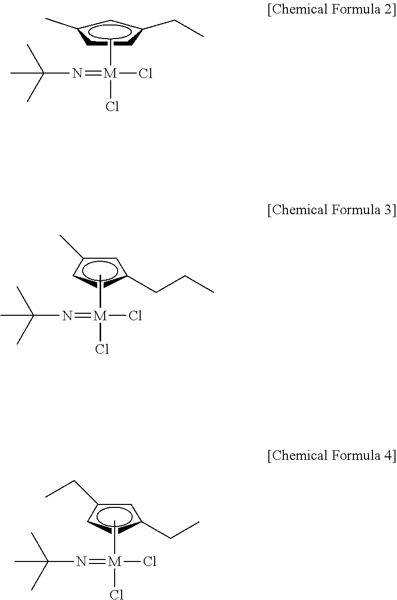
(In Chemical Formulas 2, 3, and 4, M is each independently any one selected from the group consisting of niobium (Nb), tantalum (Ta), and vanadium (V) as group 5 metal elements.).

6. The group 5 metal precursor compound of claim 1, wherein the group 5 metal precursor compound is in a liquid state at room temperature.

7. A precursor composition for deposition of a thin film containing a group 5 metal comprising the group 5 metal precursor compound of claim 1.

8. A method of forming a thin film containing a group 5 metal comprising: depositing a thin film on a substrate through a metal organic chemical vapor deposition (MOCVD) process or an atomic layer deposition (ALD) process using the group 5 metal precursor compound of claim 1.

9. The method of forming the thin film containing the group 5 metal of claim 8, wherein the deposition process is performed in a temperature range of 50 to 700° C.

10. The method of forming the thin film containing the group 5 metal of claim 8, wherein the deposition process includes transferring the group 5 metal precursor compound to the substrate through one method selected from a bubbling method, a vapor phase mass flow controller (MFC) method, a direct gas injection (DGI) method, a direct liquid injection (DLI) method, and an organic solution supply method of dissolving and transferring the group 5 metal precursor compound in an organic solvent.

11. The method of forming the thin film containing the group 5 metal of claim 10, wherein the group 5 metal precursor compound is transferred onto the substrate together with carrier gas by the bubbling method or the direct liquid injection method, and
the carrier gas includes at least one selected from the group consisting of argon (Ar), nitrogen (N₂), helium (He), and hydrogen (H₂).

12. The method of forming the thin film containing the group 5 metal of claim 8, wherein the deposition process includes supplying at least one reaction gas selected from the group consisting of water vapor (H₂O), oxygen (O₂), ozone (O₃), and hydrogen peroxide (H₂O₂), when forming the thin film containing the group 5 metal.

13. The method of forming the thin film containing the group 5 metal of claim 8, wherein the deposition process includes supplying at least one reaction gas selected from the group consisting of ammonia (NH₃), hydrazine (N₂H₄), nitrous oxide (N₂O), and nitrogen (N₂), when forming the thin film containing the group 5 metal.
